(19) United States
(12) Patent Application Publication
(10) Pub. No.: US 2009/0083595 A1
(43) Pub. Date: Mar. 26, 2009

(54) Scan test circuit

(75) Inventor: Koji Kanba, Kangawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/232,161

(22) Filed: Sep. 11, 2008

(30) Foreign Application Priority Data
Sep. 26, 2007 (JP) 249974/2007

(51) Int. Cl. G01R 31/3177; G06F 11/25

(52) U.S. Cl. 714/729; 714/E11.155

(57) ABSTRACT

When a dynamic fault test is to be performed on a plurality of divisional circuits, in order to perform the dynamic fault test also on a circuit in which the divisional circuits are combined, and to increase a fault detection rate of dynamic fault, a scan test circuit for a semiconductor device including a plurality of divisional circuits obtained by dividing a logical circuit incorporated in the semiconductor device, includes: a clock control circuit; and a first scan path and a second scan path which are provided in each of at least two of the plurality of divisional circuits. The first scan path includes peripheral scan FFs corresponding to scan FFs which transmit and receive signals to and from another one of the plurality of divisional circuits, of scan FFs included in each of the divisional circuits. The second scan path includes internal scan FFs corresponding to scan FFs other than the peripheral scan FFs, of the scan FFs included in each of the plurality of divisional circuits. The clock control circuit controls propagation and blocking of each of clock signals corresponding to the peripheral scan FFs and the internal scan FFs in each of the plurality of divisional circuits.

### BACKGROUND OF THE INVENTION

1. Field of the Invention

The present invention relates to a test circuit for a semiconductor device, and more particularly, to a scan test circuit for a semiconductor device.

2. Description of the Related Art

Up to now, with an increase in speed of a logical circuit, a dynamic fault test (dynamic test) has been performed as a test for a semiconductor device. The dynamic fault is a fault in which signal propagation takes more than a preset time. When the dynamic fault occurs in the logical circuit, the speed performance of the logical circuit reduces or the logical circuit does not normally operate.

In the dynamic fault test, for example, the logical circuit (semiconductor device) is operated at an operating clock frequency equal to or higher than that in the case of an actual circuit operation to test whether or not the logical circuit which is a circuit under test generates a normal expected value. When the operating frequency of the circuit under test at the time of the test is equal to the actual operating frequency of the circuit under test, this may be referred to as a real speed test. The dynamic fault test is to test whether or not an operating delay of the logical circuit is smaller than a desirable test rate (operating clock frequency) of the logical circuit while satisfying a reference, and hence the dynamic fault test is also referred to as a delay test.

As described above, in the dynamic fault test, a time interval between a release clock and a capture clock is short, and hence an interval of change in logical value of the circuit is short. The logical circuit (semiconductor device) is operated at high speed, and hence the influence of voltage drop of the power supply (such as instant power supply drop or IR drop) is superimposed to cause a power supply noise. Therefore, a correct test result cannot be obtained.

Thus, for example, a dynamic fault test method as shown in FIG. 10 is disclosed in JP 2005-024359 A.

According to this method, the following manner is used. A clock control circuit 503 for dividing a single clock signal source into a plurality of clock signals and controlling propagation and blocking of each of the clock signals (501 and 502) is used to realize a circuit structure in which a circuit under test 506 is divided into a plurality of groups (504 and 505) based on a supplied clock signal. The circuit structure is employed to perform a dynamic fault test with one test step on a limited group (for example, 504) of the groups of the circuit under test. The entire circuit under test is subjected to the dynamic fault test with a plurality of test steps. Note that, in JP 2005-024359 A, the test circuit having the structure described above is used to perform the dynamic fault test on a selected one of divisional circuits (for example, 504) and perform a static fault test on the other of the divisional circuits (for example, 505).

However, in the conventional example shown in FIG. 10, the dynamic fault test cannot be performed between the one divisional circuit and the other divisional circuit. A mechanism for performing the dynamic fault test between the one divisional circuit and the other divisional circuit is not included in the conventional example. In the conventional example, the dynamic fault test is performed on the one divisional circuit and the static fault test is performed on the other divisional circuit, and hence the dynamic fault test to be performed on a circuit in which the divisional circuits are combined is not included. In other words, in the conventional example, when the dynamic fault test is to be performed on the plurality of divisional circuits, the dynamic fault test to be performed on the circuit in which the divisional circuits are combined is not included, and hence a fault detection rate of dynamic fault of the entire logical circuit reduces.

### SUMMARY OF THE INVENTION

A scan test circuit according to the present invention for a semiconductor device including a plurality of divisional circuits obtained by dividing at least a part of a logical circuit incorporated in the semiconductor device, includes:

a clock control circuit; and a first scan path and a second scan path which are provided in each of at least two of the plurality of divisional circuits. The first scan path includes peripheral scan FFs corresponding to scan FFs which transmit and receive signals to and from another one of the plurality of divisional circuits, of scan FFs included in each of the plurality of divisional circuits. The second scan path includes internal scan FFs corresponding to scan FFs other than the peripheral scan FFs, of the scan FFs included in each of the plurality of divisional circuits. The clock control circuit controls propagation and blocking of each of clock signals corresponding to the peripheral scan FFs and the internal scan FFs in each of the plurality of divisional circuits.

Besides, a test method according to the present invention for a semiconductor device including the scan test circuit described above, includes: applying clocks from the clock control circuit to the peripheral scan FFs and the internal scan FFs in at least one of the plurality of divisional circuits which is a test target and to the peripheral scan FFs in at least another one of the plurality of divisional circuits which is not the test target; and performing a scan test through the first scan path and the second scan path provided in the at least one of the plurality of divisional circuits which is the test target and through the first scan path provided in the at the least another one of the plurality of divisional circuits which is not the test target.

According to the present invention, the dynamic fault test can be performed on not only a divisional circuit but also a combination with another divisional circuit, and hence a fault detection rate of dynamic fault can be increased.

### BRIEF DESCRIPTION OF THE DRAWINGS

FIG. 1 is a diagram showing a first embodiment of the present invention in this application;

FIG. 2 is a diagram showing a clock control circuit in the first embodiment of the present invention in this application;

FIG. 3 is a diagram showing a structural example of a scan FF used in the first embodiment of the present invention in this application;

FIG. 4 is a timing chart showing a test using a test circuit according to the present invention in this application;

FIG. 5 is a flow chart showing the test using the test circuit according to the present invention in this application;

FIG. 6 is an explanatory diagram showing a semiconductor device to which the test circuit according to the present invention in this application is adapted;

FIG. 7 is an explanatory diagram showing the semiconductor device to which the test circuit according to the present invention in this application is adapted;

FIG. 8 is a diagram showing a second embodiment of the present invention in this application;

FIG. 9 is a diagram showing a clock control circuit in the second embodiment of the present invention in this application; and

FIG. 10 is a diagram showing a structure of a conventional scan test circuit.

### DETAILED DESCRIPTION OF THE PREFERRED EMBODIMENTS

Hereinafter, embodiments of the present invention are described in detail with reference to the attached drawings in order to more clarify the foregoing and other objects, features and effects of the present invention.

### 1. First Embodiment

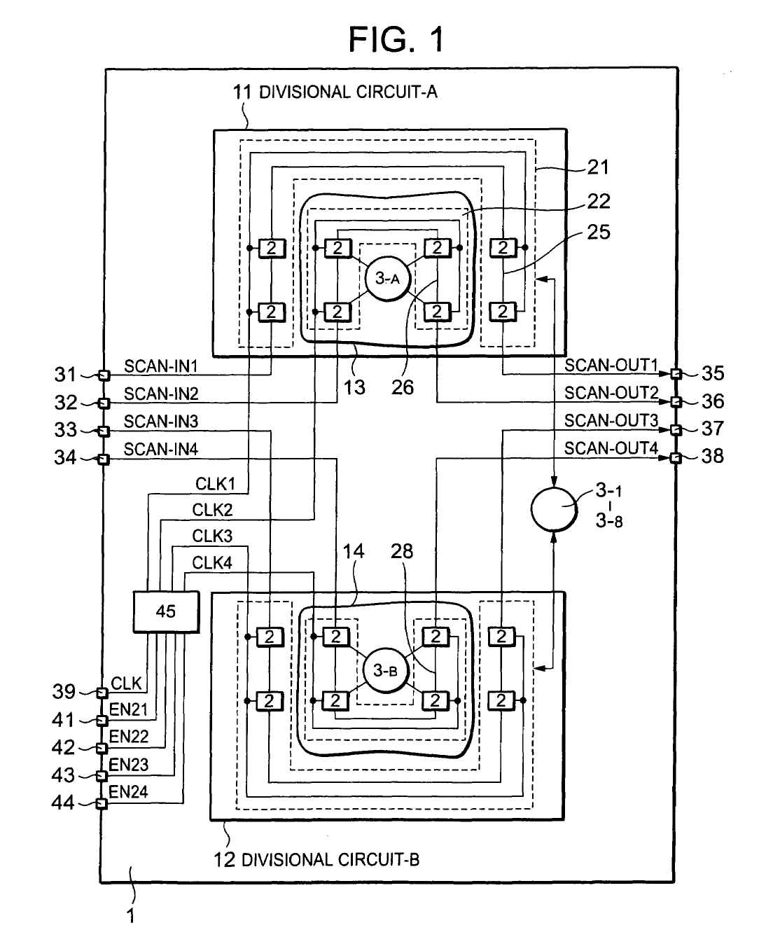

FIG. 1 is a diagram showing a first embodiment of the present invention.

A semiconductor device 1 is divided into two circuits, a divisional circuit-A (11) and a divisional circuit-B (12). The number of division of the semiconductor device 1 is determined as appropriate by a dividing method described later. In this embodiment, the case where the semiconductor device is divided into two is described for ease of explanation.

A scan test circuit according to the first embodiment of the present invention is a test circuit for the semiconductor device 1 including the two divisional circuits (11 and 12). Each of the divisional circuits (11 and 12) includes: a first scan path 25 (27) including peripheral scan flip-flops (hereinafter, referred to as FFs) 21 (23) which are scan FFs 2 for transmitting and receiving signals to and from the other divisional circuit; and a second scan path 26 (28) including internal scan FFs 22 (24) which are scan FFs other than the peripheral scan FFs. The scan test circuit according to the present invention includes a clock control circuit 45 for controlling propagation and blocking of clock signals CLK1, CLK2, CLK3, and CLK4 with respect to the peripheral scan FFs and the internal scan FFs. In other words, the scan test circuit according to the present invention includes the first and second scan paths (25, 26, 27, and 28) corresponding to the divisional circuits and the clock control circuit 45.

The divisional circuit-A (11) includes the plurality of scan FFs 2 and a combination circuit 3-A. Each of the scan FFs is a flip-flop which can perform a scan operation and is described in detail later. The scan FFs 2 of the divisional circuit-A (11) are firstly divided into two groups. A first group is a group of scan FFs which firstly transmit and receive input and output signals to and from the outside (that is, other divisional circuit) of the divisional circuit-A (11). The scan FFs belonging to the first group are referred to as the peripheral scan FFs in this specification. On the other hand, a second group is a group of scan FFs other than the peripheral scan FFs of the divisional circuit-A (11). The scan FFs belonging to the second group are referred to as the internal scan FFs in this specification. Therefore, the scan FFs of the divisional circuit-A (11) include the peripheral scan FFs 21 and the internal scan FFs 22.

Each of the peripheral scan FFs 21 of the divisional circuit-A (11) operates in synchronization with an input clock signal CLK1 (operates in one-phase synchronization). The peripheral scan FFs 21 are connected in series to constitute the scan path 25. The scan path 25 is constructed such that a scan input (SCAN-IN1) is input to the first scan FF 2 of the peripheral scan FFs 21, an output terminal of the preceding-stage scan FF 2 is connected with an input terminal of the subsequent-stage scan FF 2, and an output terminal of the final scan FF 2 of the peripheral scan FFs 21 is connected with a terminal of a scan output (SCAN-OUT1).

As in the case described above, each of the internal scan FFs 22 of the divisional circuit-A (11) operates in synchronization with an input clock signal CLK2 (operates in one-phase synchronization). The internal scan FFs 22 are connected in series to constitute the scan path 26. The scan path 26 is constructed such that a scan input (SCAN-IN2) is input to the first scan FF 2 of the internal scan FFs 22, an output terminal of the preceding-stage scan FF 2 is connected with an input terminal of the subsequent-stage scan FF 2, and an output terminal of the final scan FF 2 of the internal scan FFs 21 is connected with a terminal of a scan output (SCAN-OUT2).

In the test circuit according to the present invention, clock signals applied to the peripheral scan FFs and the internal scan FFs of one of the divisional circuits should not be shared. The scan FFs of one of the divisional circuits should not be shared a scan path (scan path chain) for peripheral portion and internal portion.

The combination circuit 3-A receives data from corresponding respective scan FFs 2 of the internal scan FF 22, performs calculation based on combination logic, and outputs a result obtained thereby to the corresponding respective scan FFs 2 of the internal scan FF 22.

Combination circuits are also provided between the peripheral scan FFs 21 and the internal scan FFs 22 and operate as in the case of the combination circuit 3-A. In order to avoid duplicated description, the combination circuits are omitted in FIG. 1 and in this description.

The divisional circuit-B (12) also has the same structure as the divisional circuit-A (11). That is, the divisional circuit-B (12) includes the peripheral scan FFs 23, the internal scan FFs 24, and a combination circuit 3-B. The peripheral scan FFs 23 constitute the scan path 27. The scan path 27 is connected with a terminal of a scan input (SCAN-IN3) and a terminal of a scan output (SCAN-OUT3). The internal scan FFs 24 constitute the scan path 28. The scan path 28 is connected with a terminal of a scan input (SCAN-IN4) and a terminal of a scan output (SCAN-OUT4).

Note that combination circuits (3-1 to 3-8) are provided between the divisional circuit-A (11) and the divisional circuit-B (12), that is, between the peripheral scan FFs 21 of the divisional circuit-A (11) and the peripheral scan FFs 23 of the divisional circuit-B (12). Not only the combination circuits 3-A and 3-B but also the combination circuits (3-1 to 3-8) correspond to test targets with respect to the present invention in this application.

The clock signals (CLK1 to CLK4) input to the scan path FFs 2 are generated by the clock control circuit 45. The clock control circuit 45 generates the clock signals CLK1 to CLK4 based on a clock signal (CLK) input from the outside through a terminal 39 and enable signals (EN21, EN22, EN23, and EN24) input from the outside through terminals 41, 42, 43, and 44.

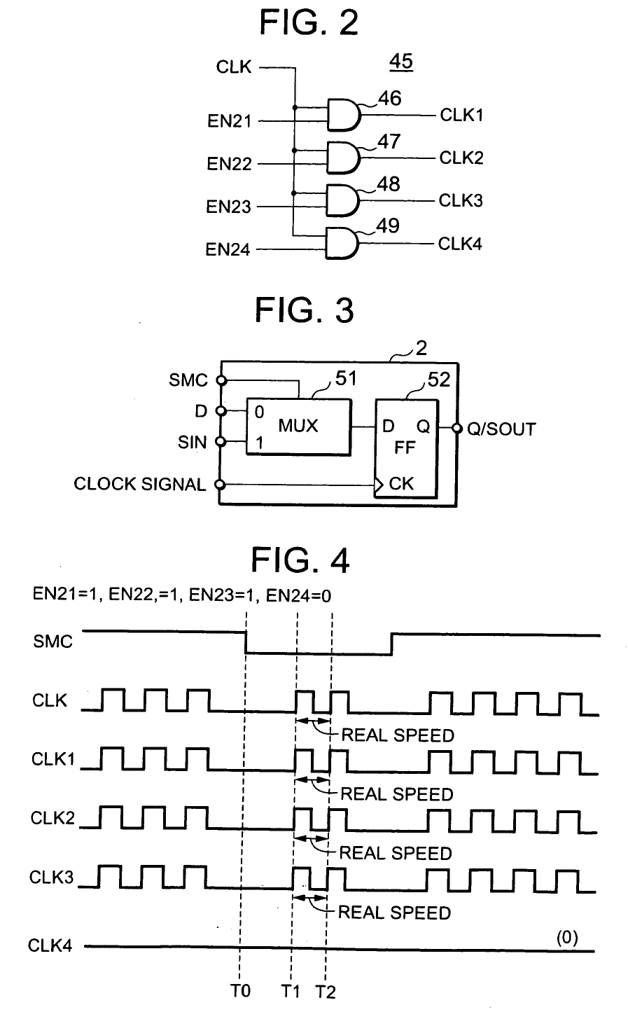

FIG. 2 shows the clock control circuit 45 in detail. As shown in FIG. 2, the clock control circuit 45 ANDs the clock signal CLK and each of the enable signals (EN21, EN22, EN23, and EN24) by AND gates 46, 47, 48, and 49 and divides AND results as the clock signals CLK1, CLK2, CLK3, and CLK4 among the respective scan FFs. For example, in a case of the clock signal CLK1, when the enable signal EN21 is 1, the input clock signal CLK is output as the clock signal CLK1 from the gate 46. When the enable signal EN21 is 0, a signal of 0 is output as the clock signal CLK1. The same is expected in a case of each of the clock signals CLK2, CLK3, and CLK4. In other words, the propagation and blocking of each of the clock signals CLK1, CLK2, CLK3, and CLK4 are controlled based on corresponding one of the enable signals (EN21, EN22, EN23, and EN24) Therefore, the clock signal CLK which is a clock source (CLK input from outside in this embodiment) is divided into the plurality of clock signals and the clock signals are divided among the peripheral scan FFs and the internal scan FFs of each of the divisional circuits (11 and 12) by the control of the clock control circuit 45.

In addition to the clock signals, shift control signals (SMC) which are not shown are divided among the respective scan FFs 2 which are the peripheral scan FFs 21 and the internal scan FFs 22, constituting the scan paths. The shift control signals are input from the outside of the semiconductor device 1 to provide a shift mode in a case of a logical value of 1 and a normal mode in a case of a logical value of 0.

Next, the scan FF 2 is described. An example of the scan FF is shown in FIG. 3. The scan FF 2 includes an MUX 51 and a D flip-plop 52. The MUX 51 receives the shift control signal (SMC) described above and outputs, to the D flip-flop 52 located at a subsequent stage, any one of input data (D) and an input scan-in signal (SIN) based on a value of the shift control signal SMC. In order that the shift control signal provides the shift mode in the case of the logical value of 1 and the normal mode in the case of the logical value of 0, when the shift control signal SMC is 1, the scan-in signal (SIN) is output to the D flip-flop 52. When the shift control signal SMC is 0, the input data (D) is output to the D flip-flop 52. The D flip-flop 52 receives the clock signal, captures data input in synchronization with the received clock signal, and outputs a value of the captured data to a terminal of an output (Q/SOUT). Note that the clock signal to be provided is any of the clock signals CLK1, CLK2, CLK3, and CLK4 generated by the clock control circuit 45, correspondingly to the divisional circuit and the group, which belong to the scan FF.

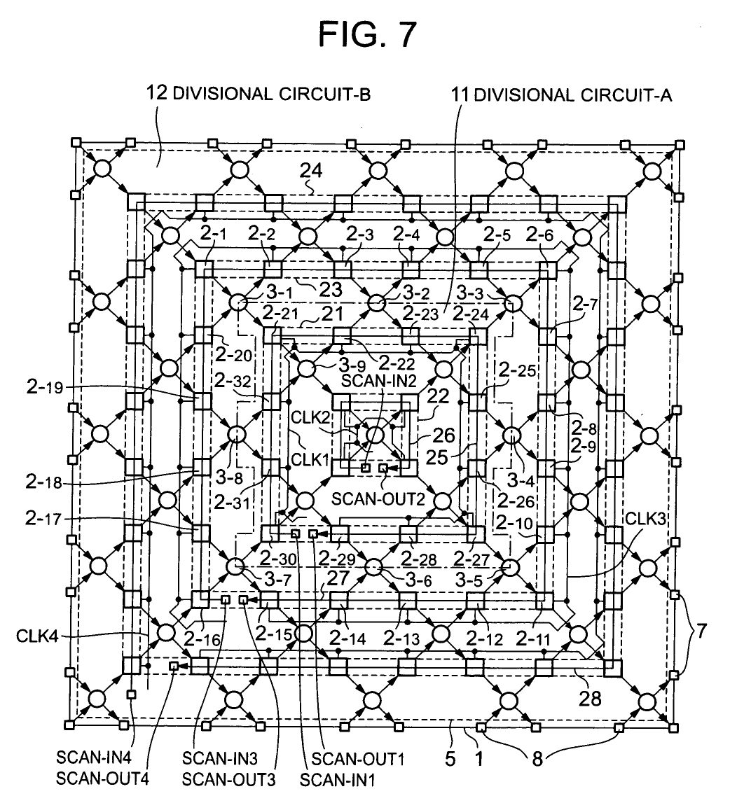

Next, the division of a logical circuit of the semiconductor device 1 is described. FIGS. 6 and 7 are explanatory diagrams showing a case where the test circuit according to the present invention in this application is adapted to a semiconductor device. As shown in FIG. 6, the semiconductor device 1 normally includes a logical circuit 5. The logical circuit 5 is an aggregation of the scan FFs 2 and combination circuits 3. As shown in FIG. 6, the combination circuit 3-1 receives outputs of scan FFs 2-1 and 2-20 for outputting hold values (data) to the combination circuit, performs processing based on logic of the combination circuit 3-1, and outputs a result obtained by the processing to subsequent-stage scan FFs 2-1 and 2-21. The subsequent-stage scan FF (for example, scan FF 2-21) outputs a hold value to a further-subsequent-stage combination circuit 3-9 at a time when a next clock signal is input. The logical circuit 5 includes the scan FFs 2 and the combination circuits 3 as described above, and hence the logical circuit 5 processes data input from input terminals 8 of the semiconductor device 1 and outputs results obtained by the processing to the outside of the semiconductor device 1 through output terminals 7. When the logical circuit 5 is to be divided into two divisional circuits as shown in FIG. 1, the logical circuit 5 is divided into two by a boundary indicated by alternate long and short dashed lines of FIG. 6. That is, the logical circuit 5 is divided by the boundary defined by the combination circuits.

As shown in FIG. 1, the two divisional regions, that is, the divisional circuit-A (11) and the divisional circuit-B (12) include the peripheral scan FFs 21 and 23 and the internal scan FFs 22 and 24. FIG. 7 shows an example of the semiconductor device 1 shown in FIG. 6 in which the test circuit according to the present invention is provided. The peripheral scan FFs 21 and 23 communicate signals between the divisional circuits. That is, the logical circuit 5 includes combination circuits 3-1 to 3-8 located between the peripheral scan FFs 21 and the peripheral scan FFs 23. The combination circuits (3-1 to 3-8) receive data from one of a group of the peripheral scan FFs 21 and a group of the peripheral scan FFs 23 and output results obtained by the processing to the other thereof.

When attention is focused on the combination circuit 3-1, outputs of the scan FFs 2-1 and 2-20 of the peripheral scan FFs 23 of the divisional circuit-B (12) are processed by the combination circuit 3-1. A result obtained by the processing is output to not only the scan FF 2-2 of the peripheral scan FFs 23 of the divisional circuit-B (12) but also the scan FF 2-21 of the peripheral scan FFs 21 of the divisional circuit-A (11).

The division of the logical circuit in view of power consumption is preferably made such that the power consumption of divisional circuits at an operating clock frequency during a dynamic fault test is estimated to such a degree that the dynamic fault test can be performed without any problem. Logical circuits which become a problem are a logical circuit whose circuit scale in the case of operating at the same clock is very large and a logical circuit in which power consumption is large in a real speed test using a real operating clock for a scan test and the real speed test is not correctly performed due to an increase in power supply noise. Therefore, each of the logical circuits is preferably divided into a plurality of parts such that the power consumption of only divisional circuits reaches a level at which there is no problem in power consumption.

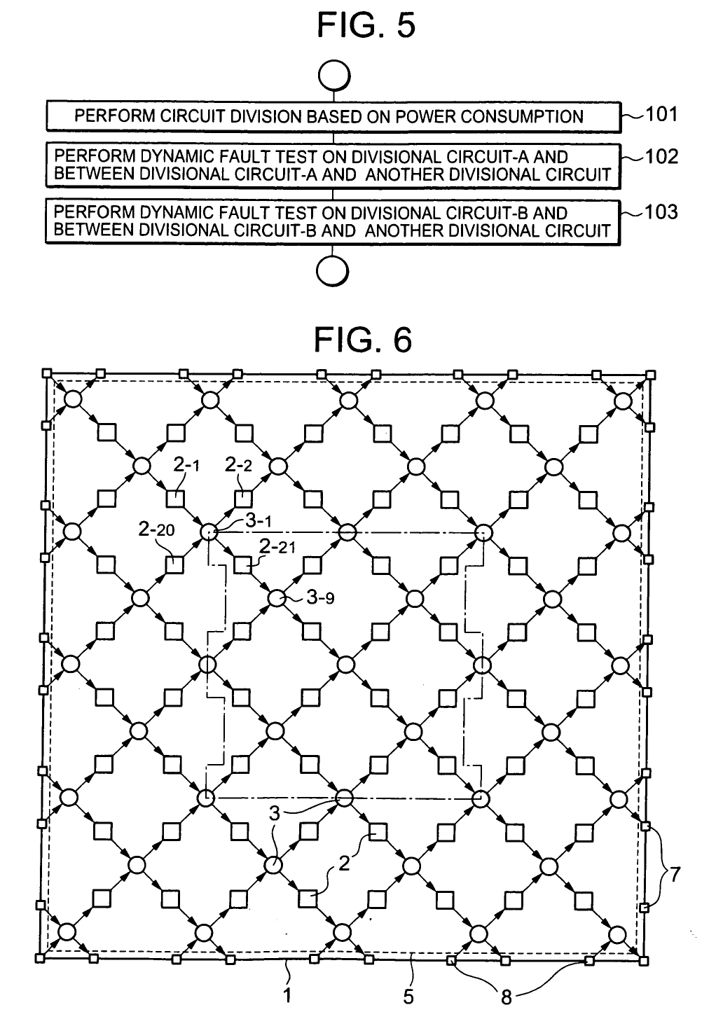

Next, the operation of the scan test circuit according to the embodiment of the present invention in this application is described with reference to FIGS. 4 and 5. FIG. 4 is a flow chart showing a test performed by the scan test circuit according to the present invention in this application. FIG. 5 is a timing chart showing a test performed using the scan test circuit according to the present invention in this application in Step 102 described later.

As shown in FIG. 5, the logical circuit 5 of the semiconductor device 1 is divided into a plurality of circuits (Step 101). The circuit division is performed as described above such that the power consumption of the divisional circuits reaches a level at which there is no problem in power consumption. Step 101 is omitted when the scan test circuit according to the present invention in this application is already provided. Hereinafter, the case where the semiconductor device 1 is divided into two circuits, that is, the divisional circuit-A and the divisional circuit-B is described.

Next, the dynamic fault test (delay test) is performed on the divisional circuit-A and between the divisional circuit-A and the divisional circuit-B (another divisional circuit) (Step 102). The detailed operation in this case is as follows.

In the scan test circuit according to the present invention in this application as shown in FIG. 1, the enable signals EN21, EN22, EN23, and EN24 are set to 1, 1, 1, and 0, respectively, to supply the clock signal CLK only to the peripheral scan FFs 21 and the internal scan FFs 22 of the divisional circuit-A (11) and the peripheral scan FFs 23 of the divisional circuit-B (12). Therefore, the clock signal CLK4 supplied to the internal scan FFs 24 of the divisional circuit-B (12) is fixed to 0. The shift mode signal (shift control signal) (SMC) is set to 1 to provide the shift mode. After that, scan data are input from the outside through the SCAN-IN1 terminal 31, the SCAN-IN2 terminal 32, and the SCAN-IN3 terminal 33 while necessary pulses of the clock signal CLK are applied. Therefore, the scan data are input to the scan FFs 2 of each of the scan paths 25, 26, and 27 to set initial values. In other words, the scan data are input to the scan FFs 2 of the peripheral scan FFs 21 and the scan FFs 2 of the internal scan FFs 22 in the divisional circuit-A (11) and the scan FFs 2 of the peripheral scan FFs 23 in the divisional circuit-B (12) to set the initial values.

After the initial values are set to the scan FFs 2 of each of the scan paths 25, 26, and 27, the shift mode signal (SMC) is set to 0 to provide the normal mode (T0). After switching to the normal mode, two pulses of the clock signal CLK are applied from the outside at a real speed (desirable clock frequency) (T1 and T2). In this case, each of the clock signals CLK, CLK1, CLK2, and CLK3 applied at the time T1 corresponds to a release clock and each of the clock signals CLK, CLK1, CLK2, and CLK3 applied at the time T2 corresponds to a capture clock. When the release clock is applied, the hold value of the scan FF 2 is replaced by data input from the combination circuit 3 located in the preceding stage of the scan FF 2 as described above. The hold value of the scan FF 2 is changed again in response to the capture clock (T2) next to T1. This is because the scan FF 2 reads new data from the combination circuit 3 at the timing of T2. Therefore, when the real speed is set between the application of the release clock (T1) and the application of the capture clock next thereto (T2), the dynamic fault test is performed.

After that, the shift mode signal (SMC) is set to 1 again to provide the shift mode (T3). After switching to the shift mode, scan data are input from the outside through the SCAN-IN1 terminal 31, the SCAN-IN2 terminal 32, and the SCAN-IN3 terminal 33 while necessary pulses of the clock signal CLK are applied. Therefore, the hold values which are test results stored in the scan FFs 2 of each of the scan paths 25, 26, and 27 are read to the outside through the SCAN-OUT1 terminal 35, the SCAN-OUT2 terminal 36, and the SCAN-OUT3 terminal 37 and then are checked against expected values prepared in advance. When the matching with the expected values occurs, the dynamic fault test is passed. When the matching therewith does not occur, the test is failed. During this reading, scan data may be input from the outside through the SCAN-IN1 terminal 31, the SCAN-IN2 terminal 32, and the SCAN-IN3 terminal 33 and the scan data may be input for a next test to the scan FFs 2 of each of the scan paths 25, 26, and 27 to set the initial values.

A series of tests including data setting to the respective scan FFs through the scan paths 25, 26, and 27, release clock application, capture clock application, reading of test results from the scan paths 25, 26, and 27, and checking against expected values are performed at least one time. After that, the matching/mis-matching with the expected values is checked and then the test of Step 102 is completed.

In Step 102, the scan data to be input and the clock signals to be applied are supplied only to the peripheral scan FFs 21 and the internal scan FFs 22 of the divisional circuit-A (11) and the peripheral scan FFs 23 of the divisional circuit-B (12). In other words, the dynamic fault test (delay test) is performed only on the divisional circuit-A and between the divisional circuit-A and the divisional circuit-B (another divisional circuit). According to the example shown in FIGS. 1 and 7, in this step, the dynamic fault test is performed also on the combination circuits 3-1 to 3-8 located between the divisional circuit-A and the divisional circuit-B (another divisional circuit).

Next, the dynamic fault test (delay test) is performed on the divisional circuit-B and between the divisional circuit-B and the divisional circuit-A (another divisional circuit) (Step 103). The enable signals EN21, EN22, EN23, and EN24 are set to 1, 0, 1, and 1, respectively, to supply the clock signal CLK only to the peripheral scan FFs 21 of the divisional circuit-A (11) and the peripheral scan FFs 23 and the internal scan FFs 24 of the divisional circuit-B (12). Setting and reading of data to the scan FFs 2 through the scan paths are performed using the scan paths 25, 27, and 28 through the SCAN-IN1 terminal 31, the SCAN-IN3 terminal 33, the SCAN-IN4 terminal 34, the SCAN-OUT1 terminal 35, the SCAN-OUT3 terminal 37, and the SCAN-OUT4 terminal 38. An operation except this is performed as in Step 102. According to the example shown in FIGS. 1 and 7, in this step, the dynamic fault test is performed also on the combination circuits 3-1 to 3-8 located between the divisional circuit-B and the divisional circuit-A (another divisional circuit).

Note that the present invention in this application can be applied to even in a case where the number of divisional circuits is plural, that is, more than two.

In this case, the logical circuit 5 of the semiconductor device 1 includes more than two divisional circuits. One of the divisional circuits is preferably constructed to have an exclusive scan path for each of a group of the peripheral scan FFs and a group of the interval scan FFs in the divisional circuit as in the case of, for example, the divisional circuit-A (11) shown in FIG. 1. A clock control circuit capable of controlling separate clock application to each of the group of the peripheral scan FFs and the group of the interval scan FFs is preferably provided. In the test circuit according to the present invention, the clock signal applied to each of the group of the peripheral scan FFs and the group of the interval scan FFs in one of the divisional circuits should not be shared. The scan FFs of one of the divisional circuits should not share a scan path (scan path chain) for peripheral portion and internal portion.

In the test, clock signals are applied to the internal scan FFs and the peripheral scan FFs of a divisional circuit which is a test target, clock signals are applied to the peripheral scan FFs of a divisional circuit which is not a test target, test data are set through scan paths each including the internal scan FFs and the peripheral scan FFs, and test results are read.

The important point is that no clock signal is applied the internal scan FFs of the divisional circuit which is not the test target while the divisional circuit which is the test target is tested. This is for the purpose of reducing the power consumption.

The example in which the number of divisional circuits of the test target is one is described. When the power consumption is within a range in which there is no problem, a plurality of divisional circuits may be simultaneously set as test targets and clock signals may be applied to the plurality of divisional circuits to perform the test. In other words, the scan test circuit and method according to the present invention in this application performs not the test in which the clock signals are applied to the entire logical circuit 5 of the semiconductor device 1 but the test in which, of the plurality of divisional circuits, at least one divisional circuit set as the test target with the power consumption being within the range in which there is no problem, is operated together with the peripheral scan FFs of the divisional circuit which is not the test target. With respect to the peripheral scan FFs of the divisional circuit which is not the test target, it is preferable to operate only the peripheral scan FFs of the divisional circuit which is not the test target and which transmits and receives signals through the peripheral scan FFs and the combination circuits of the divisional circuit which is the test target.

It is unnecessary to adapt the present invention in this application to all the divisional circuits obtained by dividing the logical circuit 5 of the semiconductor device 1. The present invention in this application may be adapted to at least two of divisional circuits obtained by dividing the logical circuit 5 of the semiconductor device 1 into at least two.

### 2. Second Embodiment

In the first embodiment, the structure is described in which the peripheral scan FFs 21 and 23 of the divisional circuit-A (11) and the divisional circuit-B (12) are separately clock-controlled. This is for the purpose of preventing the peripheral scan FFs from performing an unnecessary operation for a test.

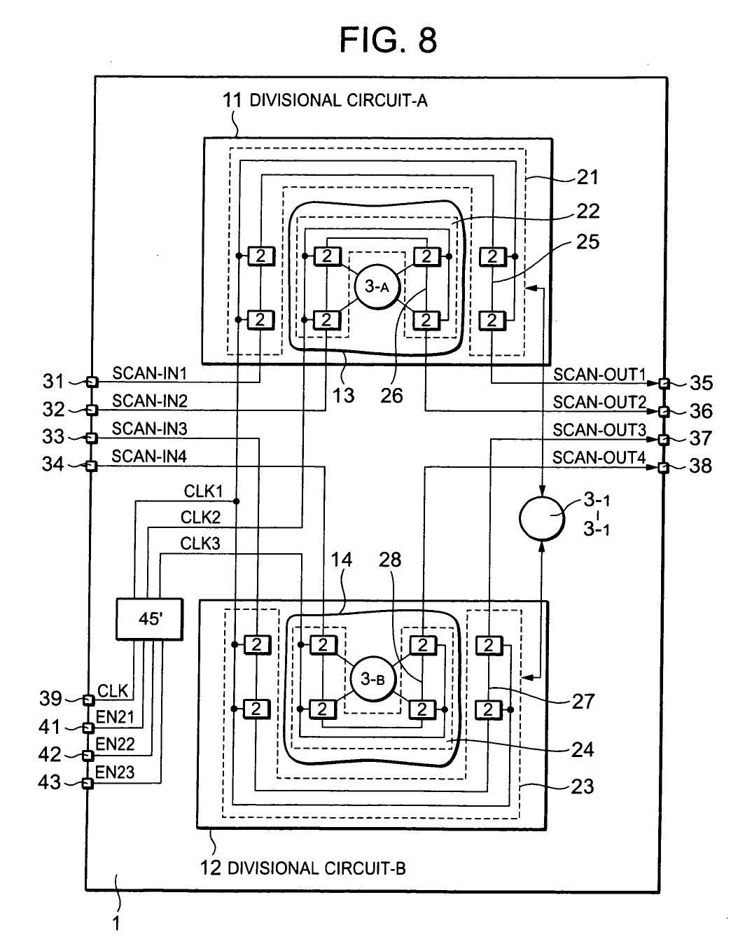

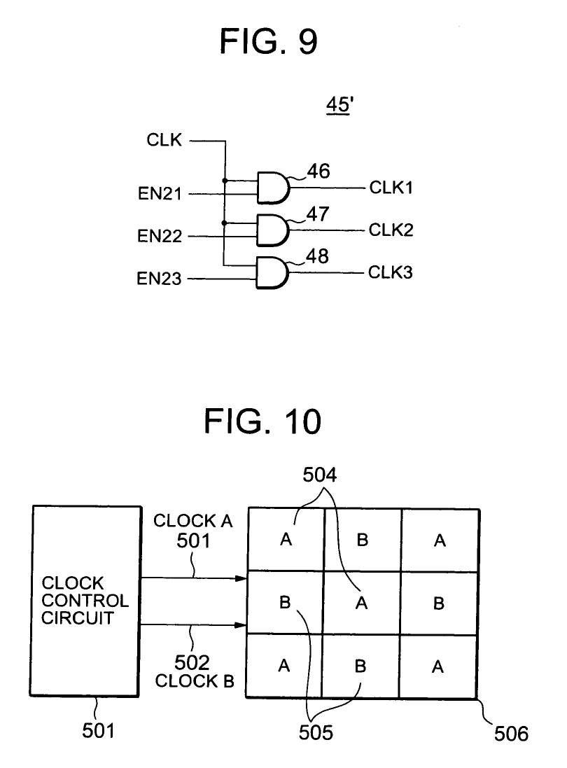

However, when the total number of peripheral scan FFs of each of the divisional circuits is sufficiently small and thus a faulty operation resulting from a power supply noise does not occur even in a case where all the peripheral scan FFs of one divisional circuit and all the peripheral scan FFs of another divisional circuit are simultaneously operated, all the peripheral scan FFs of the another divisional circuit can be operated to test the divisional circuits which are the test targets (FIG. 8). That is, the peripheral scan FFs of all the divisional circuits can be operated with a single clock. Therefore, in this case, a clock control circuit 45′ can be constructed as shown in FIG. 9.

Thus, the number of the plurality of clock signals obtained by dividing a single clock source can be reduced to simplify the clock control circuit for propagating and blocking each of the clock signals. The number of divisional clock signals is reduced, and hence a clock skew between the divisional clock signals can be more reduced. Therefore, an application to a higher-speed LSI circuit can be made.

Note that the peripheral scan FFs of two or more divisional circuits may be operated with a single clock.

As described above, the scan test circuit according to the present invention is the test circuit for the semiconductor device including the plurality of divisional circuits obtained by dividing at least a part of the logical circuit incorporated in the semiconductor device. Each of at least two of the divisional circuits includes the first scan path having the peripheral scan FFs corresponding to scan FFs which transmit and receives signals to and from another divisional circuit and the second scan path having the internal scan FFs corresponding to scan FFs other then the peripheral scan FFs. The scan test circuit further includes the clock control circuit for controlling propagation and blocking of the clock signals corresponding to the peripheral scan FFs and the internal scan FFs.

In the embodiments described above, the clock signal CLK is input from the external terminal 39. However, a clock generation source (such as PLL or ROSC) maybe separately provided to use a clock signal from the clock generation source at least at the time of a test.

Each of the clock control circuits 45 and 45′ may be any clock control circuit for separately controlling propagation and blocking of signals corresponding to the peripheral scan FFs and the internal scan FFs of each of the divisional circuits. In the embodiments, the enable signals EN21, EN22, EN23, and EN24 are input for control from the outside. Even when the signals are generated in an inner portion, the implementation of the present invention is not hindered.

When a faulty operation resulting from a power supply noise does not occur even in a case where the internal scan FFs of one divisional circuit and the internal scan FFs of another divisional circuit are simultaneously operated, the internal scan FFs of the another divisional circuit can be operated to test the divisional circuits which are the test targets. In other words, a structure may be employed in which the internal scan FFs of at least two of the divisional circuits are operated with a single clock.

The present invention is not limited to the respective embodiments described above and thus it is clear that the respective embodiments can be suitably modified without departing from the scope of the technical concept of the present invention.

What is claimed is:

1. A scan test circuit for a semiconductor device including a plurality of divisional circuits obtained by dividing at least a part of a logical circuit incorporated in the semiconductor device, comprising:
a clock control circuit; and
a first scan path and a second scan path which are provided in each of at least two of the plurality of divisional circuits,
wherein the first scan path includes peripheral scan FFs corresponding to scan FFs which transmit and receive signals to and from another one of the plurality of divisional circuits, of scan FFs included in each of the plurality of divisional circuits,
wherein the second scan path includes internal scan FFs corresponding to scan FFs other than the peripheral scan FFs, of the scan FFs included in each of the plurality of divisional circuits, and
wherein the clock control circuit controls propagation and blocking of each of clock signals corresponding to the peripheral scan FFs and the internal scan FFs in each of the plurality of divisional circuits.

2. A scan test circuit according to claim 1, wherein the clock control circuit supplies the same clock signal to the peripheral scan FFs corresponding to each of the at least two of the plurality of divisional circuits to control propagation and blocking of the same clock signal.

3. A scan test circuit according to claim 1, wherein the clock control circuit supplies the same clock signal to the internal scan FFs corresponding to each of the at least of the plurality of two divisional circuits to control propagation and blocking of the same clock signal.

4. A test method for a semiconductor device including the scan test circuit according to claim 1, comprising:
applying clocks from the clock control circuit to the peripheral scan FFs and the internal scan FFs in at least one of the plurality of divisional circuits which is a test target and to the peripheral scan FFs in at least another one of the plurality of divisional circuits which is not the test target; and
performing a scan test through the first scan path and the second scan path provided in the at least one of the plurality of divisional circuits which is the test target and through the first scan path provided in the at the least another one of the plurality of divisional circuits which is not the test target.
